(19) United States
(12) Patent Application Publication
(10) Pub. No.: US 2013/0264654 A1
(43) Pub. Date: Oct. 10, 2013

(54) Integrated Switching Device with Parallel Rectifier Element

(71) Applicants: Rolf Weis, Dresden (DE); Andreas Spitzer, Ottobrunn (DE)

(72) Inventors: Rolf Weis, Dresden (DE); Andreas Spitzer, Ottobrunn (DE)

(73) Assignee: INFINEON TECHNOLOGIES DRESDEN GMBH, Dresden (DE)

(21) Appl. No.: 13/441,038

(22) Filed: Apr. 6, 2012

(51) Int. Cl. H01L 27/06

(52) U.S. Cl. 257/392; 257/E27.026

(57) ABSTRACT

An integrated circuit includes a semiconductor body with a first semiconductor layer and a second semiconductor layer arranged adjacent the first semiconductor layer in a vertical direction of the semiconductor body. The integrated circuit further includes a switching device with a control terminal and a load path between a first load terminal and a second load terminal, and a rectifier element connected in parallel with at least one section of the load path. The switching device is integrated in the first semiconductor layer and the rectifier element is integrated in the second semiconductor layer.

### TECHNICAL FIELD

Embodiments of the present invention relate to an integrated switching device and a parallel rectifier element, and in particular to a switching device with at least one transistor and a parallel rectifier element.

### BACKGROUND

Integrated switching devices, such as power transistors, and particularly power MOS transistors, are widely used in industrial, automotive or consumer applications, such as power converter circuits, or load drive circuits for different types of loads, such as lamps or motors. There are applications in which it is desired to have a rectifier element, such as a diode, connected in parallel to the switching device. This rectifier element may act as a freewheeling element which is, in particular, useful when the switching device is employed in a circuit for driving an inductive load.

Conventional power MOSFETs have an integrated body diode that is coupled between the source and the drain terminal. The body diode allows a current to flow through the MOSFET each time the MOSFET is reverse biased. E.g., an n-type MOSFET is reverse biased when a positive voltage is applied between the source and the drain terminals. The integrated body diode of a MOSFET is formed by a body region, a drift region and a drain region of the MOSFET. The electrical properties of the body diode are dependent on the properties of these device regions. The body region, the drift region and the drain, also influence the electrical properties of the MOSFET, so that the electrical properties of the MOSFET and of the body diode cannot be designed independently.

There are applications in which it is desirable to limit the voltage across the load path (drain-source path) of a MOSFET to a voltage that is below the voltage blocking capability of the MOSFET in order to prevent the MOSFET from being operated in an Avalanche mode. This can be obtained by connecting a Zener diode or an Avalanche diode parallel to the MOSFET, with the diode being designed such that its breakdown voltage is lower than the voltage blocking capability of the MOSFET. This diode needs to be capable to dissipate energy when it is operated in the breakdown (Avalanche) mode. Thus, the diode has to be designed with a considerable volume in order to prevent the diode from being destroyed when operated in the breakdown mode.

### SUMMARY

One embodiment relates to an integrated circuit with a semiconductor body with a first semiconductor layer and a second semiconductor arranged adjacent the second semiconductor layer in a vertical direction of the semiconductor body, with a switching device with a control terminal and a load path between a first load terminal and a second load terminal, and with a rectifier element connected in parallel to at least one section of the load path. The switching device is integrated in the first semiconductor layer, and the rectifier element is integrated in the second semiconductor layer.

Those skilled in the art will recognize additional features and advantages upon reading the following detailed description, and upon viewing the accompanying drawings.

### BRIEF DESCRIPTION OF THE DRAWINGS

Examples will now be explained with reference to the drawings. The drawings serve to illustrate the basic principle, so that only aspects necessary for understanding the basic principle are illustrated. The drawings are not to scale. In the drawings the same reference characters denote like features.

FIG. 1 illustrates a circuit diagram of an integrated circuit with a switching device and with a rectifier element connected in parallel with a load path of the switching device.

FIG. 2 illustrates a circuit diagram of an integrated circuit with a switching device including a first switching element.

FIG. 3 illustrates a circuit diagram of an integrated circuit with a switching device including a first switching element and a plurality of second switching elements.

FIG. 4 illustrates a circuit diagram of an integrated circuit according to a further embodiment.

FIG. 5 schematically illustrates a vertical cross sectional view of a semiconductor body with an integrated circuit according to a first embodiment.

FIG. 6 schematically illustrates a vertical cross sectional view of a semiconductor body with an integrated circuit according to a first embodiment.

FIG. 7 illustrates one embodiment of a connector shown in FIG. 6.

FIG. 8 schematically illustrates a vertical cross sectional view of a semiconductor body with an integrated circuit according to a second embodiment.

FIG. 9 schematically illustrates a vertical cross sectional view of a semiconductor body with an integrated circuit according to a third embodiment.

FIG. 10 schematically illustrates a vertical cross sectional view of a semiconductor body with an integrated circuit according to a third embodiment.

FIG. 11 schematically illustrates a vertical cross sectional view of a semiconductor body with an integrated circuit according to a further embodiment.

FIG. 12 schematically illustrates a vertical cross sectional view of a first switching element according to a first embodiment.

FIG. 13 that includes FIGS. 13A to 13C illustrates a first embodiment of one second semiconductor device implemented as FINFET.

FIG. 14 that includes FIGS. 14A to 14C illustrates a second embodiment of one second semiconductor device implemented as FINFET.

FIG. 15 illustrates a vertical cross sectional view of a semiconductor body according to a first embodiment in which a first semiconductor device and a plurality of second semiconductor devices are implemented in one semiconductor fin.

FIG. 16 illustrates a vertical cross sectional view of a semiconductor body according to a second embodiment in which a first semiconductor device and a plurality of second semiconductor devices are implemented in one semiconductor fin.

FIG. 17 illustrates a top view of a semiconductor body according to a third embodiment in which a first semiconductor device and a plurality of second semiconductor devices each including several FINFET cells are implemented.

FIG. 18 illustrates a vertical cross sectional view of one second semiconductor device including several FINFET cells connected in parallel.

FIG. 19that includes FIGS. 19A to 19C illustrates a further embodiment of one second semiconductor device including several FINFET cells connected in parallel.

FIG. 20 illustrates two second semiconductor devices of the type illustrated in FIG. 19 connected in series.

### DETAILED DESCRIPTION

In the following Detailed Description, reference is made to the accompanying drawings, which form a part thereof, and in which is shown by way of illustration specific embodiments in which the invention may be practiced. In this regard, directional terminology, such as “top”, “bottom”, “front”, “back”, “leading”, “trailing” etc., is used with reference to the orientation of the FIGs. being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

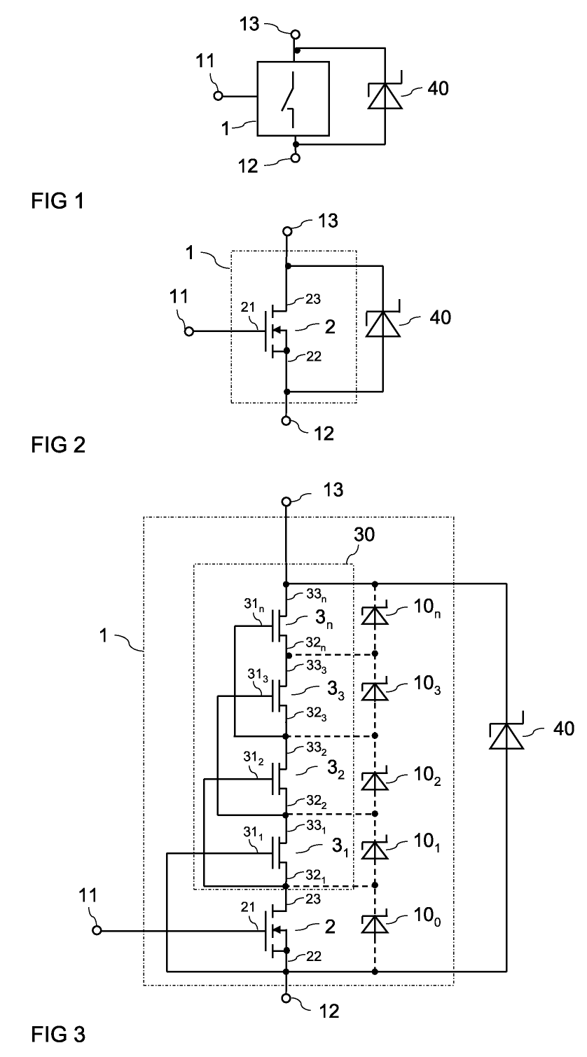

FIG. 1 shows a circuit diagram of an integrated circuit that includes a switching device 1 with a control terminal 11 and a load path between a first load terminal 12 and a second load terminal 13. In FIG. 1, the switching device 1 is only schematically illustrated as a circuit block. The switching device 1 is a controllable switching device and can be switched on and off through a control or drive signal that can be applied to the control terminal 11. When the switching device 1 is switched on, it provides a low-ohmic conducting path between the first and second load terminals 12, 13. When the switching device is switched off, the conducting path between the first and second load terminals 12, 13 is interrupted, so that the path between the first and second load terminals 12, 13 is extremely high-ohmic. The switching device 1 of FIG. 1 can be used as an electronic switch in a variety of industrial, automotive, or consumer applications.

Referring to FIG. 1, the integrated circuit further includes a rectifier element 40 connected in parallel with at least one section of the load path of the switching device 1. Just for illustration purposes, the rectifier element 40 of FIG. 1 is connected in parallel with the complete load path of the switching device 1. However, this is only an example. According to a further embodiment, the load path of the switching device 1 includes two or more load path sections connected in series, wherein the rectifier element 40 is connected in parallel with one of these sections or in parallel with several of these sections, but not in parallel with the complete load path.

According to one embodiment, the rectifier element 40 is implemented as a Zener diode or as an Avalanche diode. In the embodiment illustrated in FIG. 1, an anode of the diode 40 is connected to the first load terminal 12, while a cathode is connected to the second load terminal 13 of the switching device 1. A rectifier element 40 implemented as a Zener diode or an Avalanche diode has two functions: First, it allows a current to flow between the first and second load terminals 12, 13 independent of a switching state of the switching device 1, when a voltage between the first and second load terminals 12, 13 has a certain polarity. In the embodiment illustrated in FIG. 1, the rectifier element 40 always allows a current to flow between the first and second load terminals 12, 13, when a positive voltage is applied between the first load terminal 12 and the second load terminal 13. Second, the rectifier element 40 limits a voltage between the second load terminal 13 and the first load terminal 12 to a maximum given by the breakdown voltage of the diode 40. Thus, diode 40 acts as a freewheeling element, which can be required in applications in which a current through an inductive load is to be controlled, and acts a protection element for protecting the switching device 1 from voltages higher than the breakdown voltage of the diode 40.

The switching device 1 can be implemented in many different ways. There are switching devices such as, e.g. MOSFETs, that have an integrated diode (body diode). However, unlike the additional diode 40 shown in FIG. 1, electrical properties of a body diode of a MOSFET cannot be designed independent of the electrical properties of the MOSFET itself.

FIG. 2 illustrates a switching device 1 according to a first embodiment. In this embodiment, the switching device 1 includes a first switching element 2 with a control terminal 21 connected to control terminal 11 of the switching device 1, with a first load terminal 22 being connected to the first load terminal 12 of the switching device 1, and with a second load terminal 23 being connected to the second load terminal 13 of the switching device 1. The first switching element 2 of FIG. 2 is implemented as a transistor, specifically as a MOSFET. In this case, the control terminal 21 is the gate terminal, the first load terminal 22 is the source terminal, and the second load terminal 23 is the drain terminal of the MOSFET. It is commonly known that a MOSFET is a voltage-controlled semiconductor device that can be operated like a voltage-controlled electronic switch. Specifically, a MOSFET can be switched on and off by applying a suitable drive voltage between the gate terminal, such as gate terminal 21 in FIG. 2, and the source terminal, such as source terminal 22 of FIG. 2. The MOSFET illustrated in FIG. 2 is an n-type enhancement MOSFET. However, this is only an example. Instead of an n-type MOSFET a p-type MOSFET could be used as well. Further, the first switching element 2 could also be implemented as an IGBT.

The MOSFET 2 of FIG. 2 has an integrated body diode (not illustrated) that is parallel to the rectifier element (diode) 40. Further, the MOSFET 2 has a voltage blocking capability. The voltage blocking capability is defined by the maximum voltage that the MOSFET can withstand (without breaking through) when it is switched off. According to one embodiment, the breakdown voltage of the diode 40 is lower than the voltage blocking capability of the MOSFET 2. In this case, the diode 40 prevents the voltage between the second load terminal 13 and the first load terminal 12 to reach the breakdown voltage of the MOSFET 2.

FIG. 3 illustrates a second embodiment of a switching device 1. In this embodiment, the switching device includes the first switching element 2 and a plurality of second switching elements 31-3n. The control terminal of the first switching element 2 is connected to the control terminal of the switching device 1, and the load path 22-23 of the first switching element 2 is connected in series with load paths of the second switching elements 31-3n. The series circuit with the load paths of the first switching element 1 and the second switching elements 31-3n is connected between the first and second load terminals 12, 13 of the switching device 1. In the embodiment of FIG. 3, the first load terminal 22 of the first switching element 2 is connected to the first load terminal of the switching device 1.

Like the first switching element of FIG. 2, the first switching element 2 according to FIG. 3 is implemented as a transistor, specifically as a MOSFET where the control terminal 21 is a gate terminal and the first and second 22, 23 load terminals are source and drain terminals, respectively.

In FIG. 3 as well as in the following figures reference number “3” followed by a subscript index denotes the individual second switching elements. Same parts of the individual second switching elements, such as control terminals and load terminals, have the same reference character followed by a subscript index. For example, 31 denotes a first one of the second switching elements that has a control terminal 311 and first and second load terminals 321, 331. In the following, when reference is made to an arbitrary one of the second switching elements or to the plurality of the second switching elements, and when no differentiation between individual second switching elements is required, reference numbers 3, 31, 32, 33 without indices will be used to denote the second switching elements and their individual parts.

The second switching elements 3 are implemented as transistors in the embodiment illustrated in FIG. 1 and will be referred to as second transistors in the following, while the first switching element will be referred to as first transistor in the following. Each of the second transistors 3 has a control terminal 31 and a load path between a first load terminal 32 and a second load terminal 33. The load paths 32-33 of the second switching elements are connected in series with each other so that the first load terminal of one second transistor is connected to the second load terminal of an adjacent second transistor. Further, the load paths of the second transistors 3 are connected in series with the load path 22-23 of the first switching element 2, so that the first switching element 2 and the plurality of second transistors 3 form a cascode-like circuit.

Referring to FIG. 1, there are n second transistors 3, with n>1. From these n second transistors 3, a first second transistors 3₁ is the second transistor that is arranged closest to first switching element 1 in the series circuit with the n second transistors 3 and has its load path 32₁-33₁ directly connected to the load path 22-23 of the first switching element 1. An n-th second transistor 3ₙ is the second transistor that is arranged most distant to first switching element 2 in the series circuit with the n second transistors 3. In the embodiment illustrated in FIG. 1, there are n=4 second transistors 3. However, this is only an example, the number n of second transistors 3 can be selected arbitrarily, namely dependent on a desired voltage blocking capability of the switching element arrangement. This is explained in greater detail herein below.

Each of the second switching elements 3 has its control terminal 31 connected to one of the load terminals of another one of the second switching elements 3 or to one of the load terminals of the first switching element 2. In the embodiment illustrated in FIG. 1, the 1st second transistor 3₁ has its control terminal 31₁ connected to the first load terminal 22 of the first switching element 2. Each of the other second transistors 3₂-3ₙ₋₁ have their control terminal 31₂-31ₙ connected to the first load terminal 32₁-32₃ of the second transistor that is adjacent in the series circuit in the direction of the first switching element 2. Assume, for explanation purposes, that 3ᵢ is one of the second transistors 3₂-3ₙ other than the first transistor 3₁. In this case, the control terminal 31ᵢ of this second transistor (upper second transistor) 3ᵢ is connected to the first load terminal 32ᵢ₋₁ of an adjacent second transistor (lower second transistor) 3ᵢ₋₁. The first load terminal 32ᵢ₋₁ of the lower second transistor 3ᵢ₋₁ to which the control terminal of the upper second transistor 3, is connected to is not directly connected to one of the load terminals 32ᵢ, 33ᵢ of this upper second transistor 3ᵢ. According to a further embodiment (not illustrated), a control terminal 31ᵢ of one second transistor 3ᵢ is not connected to the first load terminal 31ᵢ₋₁ of that second transistor 3ᵢ₋₁ that is directly connected to the second transistor 3ᵢ, but is connected to the load terminal 32ᵢ₋ₖ of a second transistor 3ᵢ₋ₖ, with k>1, farther away from the transistor. If, for example, k=2, then the control terminal 31, of the second transistor 3ᵢ is connected to the first load terminal 32ᵢ₋₂ of the second transistor 3ᵢ₋₂ that is two second transistors away from the second transistor 3ᵢ in the direction of the first switching element in the series circuit.

Referring to FIG. 1, the first switching element 2 and the second switching elements 3 can be implemented as MOSFETs. Each of these MOSFETs has a gate terminal as a control terminal 21, 31, a source terminal as a first load terminal 22, 32, and a drain terminal as a second load terminal 23, 33. MOSFETs are voltage controlled devices that can be controlled by the voltage applied between the gate and source terminals (the control terminal and the first load terminal). Thus, in the arrangement illustrated in FIG. 1, the 1st second transistors 3₁ is controlled through a voltage that corresponds to the load path voltage of the first switching element 2, and the other second transistors 3ᵢ are controlled through the load path voltage of at least one second transistor 3ᵢ₋₁ or 3ᵢ₋₂. The “load path” voltage of one MOSFET is the voltage between the first and second load terminal (drain and source terminal) of this MOSFET.

In the embodiment illustrated in FIG. 3, the first switching element 2 is a normally-off (enhancement) transistor, while the second transistors 3 are normally-on (depletion) transistors. However, this is only an example. Each of the first switching element 2 and the second transistors 3 can be implemented as a normally-on transistor or as a normally-off transistor. The individual transistors can be implemented as n-type transistors or as p-type transistors.

Implementing the first switching element 2 and the second transistors 3 as MOSFETs is only an example. Any type of transistor can be used to implement the first switching element 2 and the second transistors 3, such as a MOSFET, a MISFET, a MESFET, an IGBT, a JFET, a FINFET, a nanotube device, an HEMT, etc. Independent of the type of device used to implement the first switching element 2 and the second switching elements 3, these devices are connected such that each of the second transistors 3 is controlled by the load path voltage of at least one other second transistor 3 or the first switching element 2 in the series circuit.

The switching device 1 with the first switching element 2, implemented as a transistor, and with the second switching elements 3, each implemented as a transistor, can be switched on and off like a conventional transistor by applying a suitable drive voltage to the first switching element 2. The control terminal 21 of the first switching element 2 forms a control terminal 11 of the switching device, and the first load terminal 21 of the first switching element 2 and the second load terminal of the n-th second transistor 3ₙ form the first and second load terminals 12, 13, respectively, of the switching device.

The operating principle of the switching device 1 of FIG. 3 is explained in the following. Just for explanation purposes it is assumed that the first semiconductor device 2 is implemented as an n-type enhancement MOSFET, that the second transistors 3 are implemented as n-type depletion MOSFETs or n-type JFETs, and that the individual devices 2, 3 are interconnected as illustrated in FIG. 1. The basic operating principle, however, also applies to a switching device 1 implemented with other types of first and second semiconductor devices.

It is commonly known that depletion MOSFETs or JFETs, that can be used to implement the second transistors 3, are switching elements that are in an on-state when a drive voltage (gate-source voltage) of about zero is applied, while MOSFETs or JFETs are in an off-state when the absolute value of the drive voltage is higher than a pinch-off voltage of the device. The “drive voltage” is the voltage between the gate terminal and the source terminal of the device. In an n-type MOSFET or JFET the pinch-off voltage is a negative voltage, while the pinch-off voltage is a positive voltage in a p-type MOSFET or JFET.

When a (positive) voltage is applied between the second and first load terminals 13, 12 and when the first transistor 2 is switched on by applying a suitable drive potential to the control terminal 11, the 1st second transistor 3₁ is conducting (in an on-state), the absolute value of the voltage across the load path 22-23 of the first transistor 2 is too low so as to pinch-off the 1st second transistor 3₁. Consequently, the second transistor 3₂ controlled by the load path voltage of second transistor 3₁ is also starting to conduct, etc. In other words, the transistor 2 and each of the second transistors 3 are finally conducting so that the switching device 1 is in an on-state. When the switching device 1 is in an on-state and when the first transistor 2 is switched off, the voltage drop across the load path of the first transistor 2 increases, so that the 1st second transistor 3₁ starts to switch off when the absolute value of the load-path voltage reaches the pinch-off voltage of the 1st of the second transistors 3. When a positive voltage is applied between the second load terminal 13 and the first load terminal 12 of the switching device 1, the voltage between the second load terminal 23 and the first load terminal 22 of the first transistor 2 is also a positive voltage when the first switching element 2 switches off. In this case, the gate-source voltage of the 1st second transistor 3₁ is a negative voltage suitable to pinch this transistor 3₁ off.

When the 1st second transistor 3₁ is switched off, the voltage drop across its load path increases so that the 2nd second transistor 3₂ is switched off, which in turn switches off the 3rd second transistor, and so on, until each of the second transistors 3 is switched off and the switching device 1 is finally in a stable off-state. The external voltage applied between the second and first terminals 13 and 12 switches as many 2nd transistors from the on-state to the off-state as required to distribute the external voltage over the first switching element 2 and the second transistors 3. When applying a low external voltage, some second transistors are still in the on-state, while others are in the off-state. The number of second transistors that are in the off-state increase as the external voltage increases. Thus, when a high external voltage is applied, that is in the range of the voltage blocking capability of switching device 1, the first transistor 2 and each of the second switching elements 3 are in the off-state

When the switching device 1 is in an off-state and when the first transistor 2 is switched on, the voltage drop across the load path of the first transistor 2 decreases so that it switches on the 1st second transistor 3₁, which in turn switches on the 2nd second transistor 3₂, and so on. This continues until each of the second transistors 3 is again switched on.

The switching states of the second switching elements 3 connected in series with the first switching element 2 are dependent on the switching state of the transistor 2 and follow the switching state of the first witching element 2. Thus, the switching state of the switching device 1 is defined by the switching state of the first switching element 2. The switching device 1 is in an on-state when the first switching element 2 is in an on-state, and switching device 1 is in an off-state when the first switching element 2 is in an off-state.

The switching device 1 has a low resistance between the first and second load terminals 12, 13 when it is in an on-state, and has a high resistance between the first and second load terminals 12, 13 when it is in an off-state. In the on-state, an ohmic resistance between the first and second load terminals 12, 13 corresponds to the sum of the on-resistances R_{ON} of the first switching element 2 and the second switching elements 3. A voltage blocking capability, which is the maximum voltage that can be applied between the first and second load terminals 12, 13 when the switching device 1 is in an off-state before an Avalanche breakthrough sets in, corresponds to the sum of the voltage blocking capabilities of the first switching element 2 and the second switching elements 3. The first switching element 2 and the individual second switching elements may have relatively low voltage blocking capabilities, such as voltage blocking capabilities of between 3V and 50V. However, dependent on the number n of second switching elements 3 a high overall voltage blocking capability of up to several 100V, such as 600V or more, can be obtained.

The voltage blocking capability and the on-resistance of the switching device 1 are defined by the voltage blocking capabilities of the first switching element 2 and the second switching elements 3 and by the on-resistances of the first switching element 2 and the second switching elements 3, respectively. When significantly more than two second switching elements are implemented (n>>2), such as more than 5, more than 10, or even more than 20 second switching elements 3 are implemented, the voltage blocking capability and the on-resistance of the switching device 1 are mainly defined by the arrangement 30 with the second switching elements 3. The switching device 1 can be operated like a conventional power transistor, where in a conventional power transistor, an integrated drift region mainly defines the on-resistance and the voltage blocking capability. Thus, the arrangement 30 with the second switching elements 3 has a function that is equivalent to the drift region in a conventional power transistor. The arrangement 30 with the second transistors 30 will, therefore, be referred to as active drift region (ADR). The switching device 1 of FIG. 3 can be referred to as ADZ transistor or ADR transistor (ADZ transistor) or as ADRFET (ADZFET), when the first switching element 1 is implemented as a MOSFET.

When the switching device 1 is in an off-state, the voltage applied between the first and second load terminals 12, 13 is distributed such that a part of this voltage drops across the load path 22-23 of the first switching element 2, while other parts of this voltage drop across the load paths of the second switching elements 3. However, there may be cases in which there is no equal distribution of this voltage to the second switching elements 3. Instead, those second switching elements 3 that are closer to the first switching element 2 may have a higher voltage load than those second switching elements 3 that are more distant to the first switching element 2.

In order to more equally distribute the voltage to second switching elements 3, the switching device optionally includes voltage limiting means 101-10n that are configured to limit or clamp the voltage across the load paths of second switching elements 3. Optionally, a clamping element 100 is also connected in parallel to the load path (between the source and drain terminals) of the first switching element 2. These voltage clamping means 100-10n can be implemented in many different ways. Just for illustration purposes the clamping means 100-10n illustrated in FIG. 3 include Zener diodes 100-10n, with each Zener diode 100-10n being connected in parallel with the load path of one of the second switching elements 3 and, optionally, the first second switching element 2.

Instead of the Zener diodes 10₀-10ₙ, tunnel diodes, PIN diodes, avalanche diodes, or the like, may be used as well. According to a further embodiment (not illustrated), the individual clamping elements 10₀-10ₙ are implemented as transistors, such as, for example, p-type MOSFETs when the second switching elements 3 are n-type MOSFETs. Each of these clamping MOSFETs has its gate terminal connected to its drain terminal, and the load path (the drain-source path) of each MOSFET is connected in parallel with the load path of one second switching element 3.

The individual clamping elements, such as the Zener diodes 10₀-10ₙ illustrated in FIG. 3 can be integrated in the same semiconductor body as the first switching element 2 and the second switching elements 3. However, these clamping elements could also be implemented as external devices arranged outside the semiconductor body.

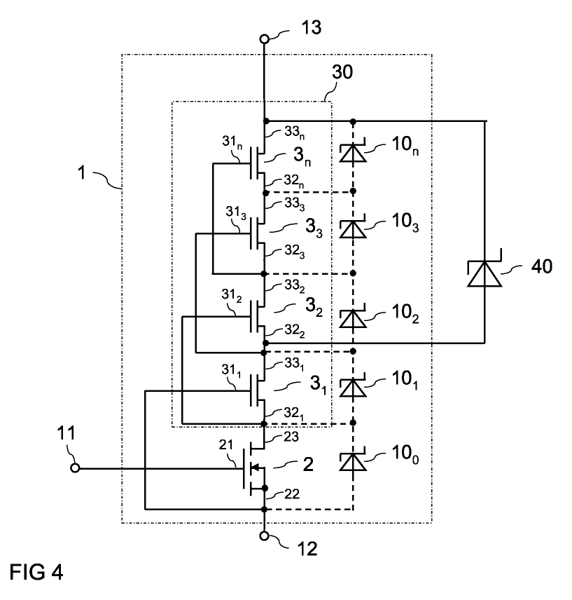

FIG. 4 illustrates an embodiment of a circuit in which the diode 40 is connected only in parallel with a section of the load path of the switching device 1. The switching device of FIG. 4 corresponds to the switching device explained with reference to FIG. 3 before and includes a first switching element 2 and a plurality of second switching elements 3. Referring to FIG. 4, the diode 40 is connected in parallel with a series circuit that includes load paths of several second switching elements 3. In the embodiment of FIG. 4, the diode 40 is connected in parallel with a series circuit including the second switching elements 3₂, 3₃, 3ₙ. However, this is only an example. The diode 40 can be connected in parallel with only one of the first and second switching elements 2, 3 or with any series circuit including two or more load paths of a group of switching elements 2, 3 connected in series.

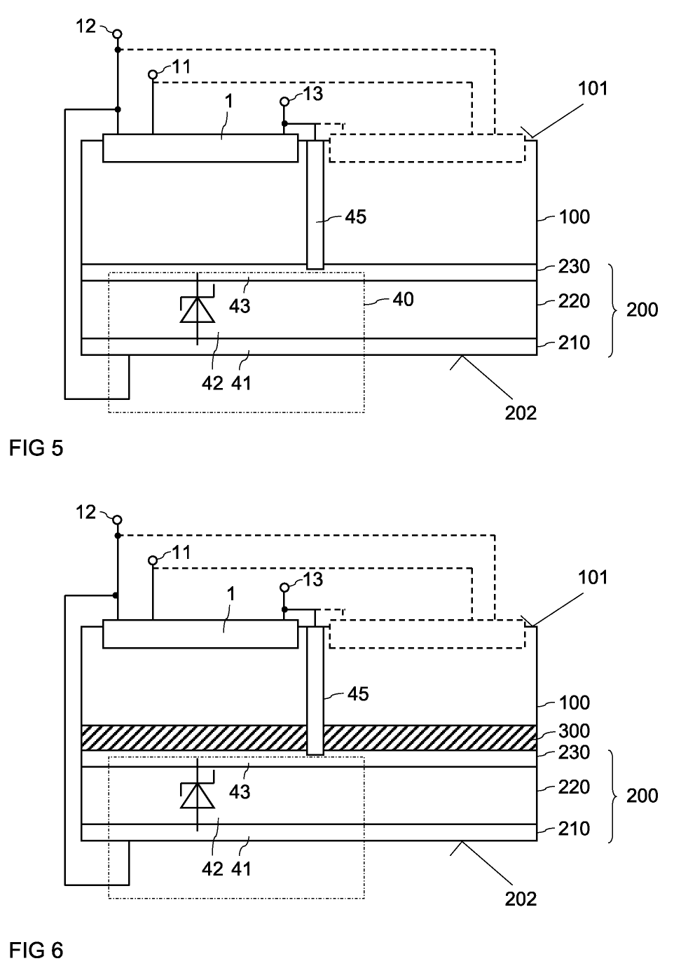

FIG. 5 illustrates a vertical cross sectional view of a semiconductor body in which the switching device 1 and the rectifier element 40 are integrated. The semiconductor body includes a first semiconductor layer 100 in which the switching device 1 is integrated, and a second semiconductor layer 200 in which the rectifier element 40 is integrated. The second semiconductor layer 200 is adjacent the first semiconductor layer 100 in a vertical direction of the semiconductor body. The “vertical direction” of the semiconductor body is a direction perpendicular to a first surface 101 of the first semiconductor layer 100 and of the semiconductor body, respectively. The switching device 1, which is only schematically illustrated as a circuit block in FIG. 5, is integrated in the region of the first surface 101 of the semiconductor layer 100. A control terminal 11 and the first and second load terminals 12, 13 are accessible at the first surface 101. These terminals are only schematically illustrated in FIG. 5. The first and second load terminals 12, 13 are distant in a lateral direction, which is a direction parallel to the first surface 101.

The first semiconductor layer 100 has a basic doping of a first doping type or is intrinsic. Active regions of the first switching element (2 in FIGS. 2, 3 and 4) or of the optional second switching elements (3 in FIGS. 3 and 4), such as source, body and drain regions when the switching elements are implemented as MOSFETs, are integrated in the first semiconductor layer 100 close to the first surface 101. Embodiments for implementing the switching device 1 with at least the first switching element 2 are explained below. The first switching element 2 and the optional second switching elements 3 are lateral devices, which means that load paths (drain-source paths) of these devices mainly extend in the lateral direction of the first semiconductor layer 100, which is the direction parallel to the first surface 101.

Referring to FIG. 5, the diode 40 is a vertical semiconductor device, a load path of the diode 40 mainly extends in a vertical direction of the semiconductor body. The diode 40 is formed by three partial layers of the second semiconductor layer 200, namely a first partial layer 210 of the first doping type, a second partial layer 220 adjoining the first partial layer 210 and a third partial layer 230 adjoining the second partial layer 220 and having the second doping type. The first partial layer 210 forms a first emitter of the diode 40, the second partial layer 220 forms a base of the diode 40, and the third partial layer 230 forms a second emitter. In the embodiment illustrated in FIG. 5, the first doping type is a p-type, so that the first partial layer 210 forms a p-emitter (anode) of the diode, while the second doping type is an n-type, so that the first partial layer 230 forms an n-emitter (cathode) of the diode 40. The base region 42 is either of the first doping type, of the second doping type, or intrinsic. The doping concentration of the base region 42 is lower than the doping concentration of the first and second emitter regions 41, 43. According to one embodiment, the doping concentration of the base region 42 is lower than 1E15 cm⁻³, and in particular lower than 1E14 cm⁻³, or even lower than 5E13 cm⁻³.

The electrical properties of the diode 40, such as breakdown voltage or on-resistance, are defined by the doping concentrations of the individual partial layers 210, 220, 230 or the emitter and base regions, respectively, and by the length of the base region 42. The length of the base region 42 is defined by the thickness of the second partial layer 220, where the thickness is the vertical dimension of the second partial layer 220. These parameters, namely the doping type, the doping concentration, and the length of the base region 42, can be designed independent of the switching device 100 in the first semiconductor layer 100. Further, the overall circuit can be implemented in a space saving manner because the switching device 100 and the diode are integrated one above the other in the same semiconductor body, namely the semiconductor body including the first semiconductor layer 100 and the second semiconductor layer 200.

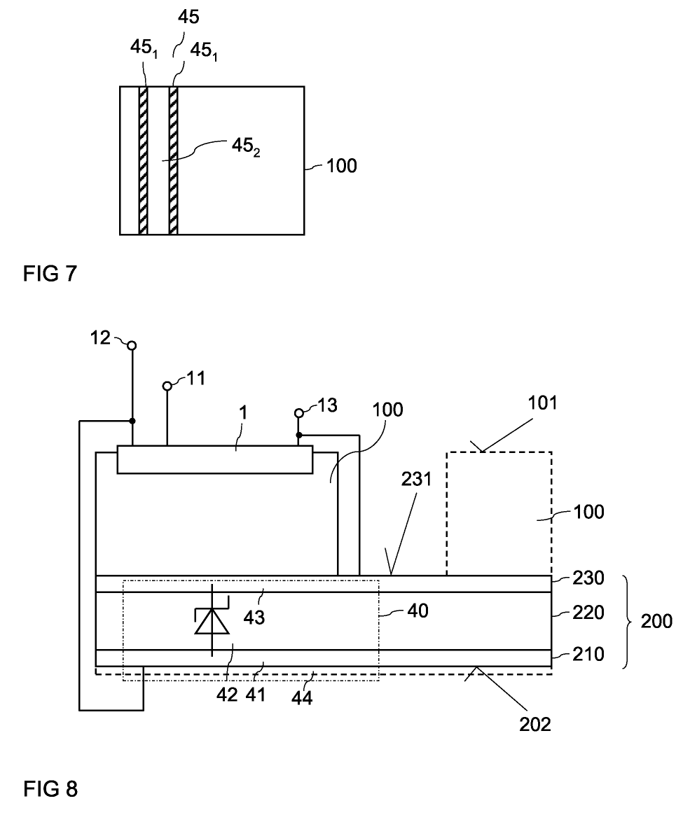

In the embodiment illustrated in FIG. 5, the first partial layer 210 forms a second surface of the semiconductor body opposite the first surface 101. Further, the second semiconductor layer 200, specifically the third partial layer 230 adjoins the first semiconductor layer 100. The first partial layer 210 forming the first emitter 41 of the diode 40 is electrically connected to the first load terminal 12, while the third partial layer 230 forming the second emitter region 43 of the diode 40 is electrically connected to the second load terminal 13. For connecting the second load terminal 13 to the third partial layer 230 a connector 45 is connected to the second load terminal 13 at the first surface 101 and extends in a vertical direction through the first semiconductor layer 100 to or into the third partial layer 230. The connector 45 is electrically conducting or includes an electrically conducting core (see the embodiment of FIG. 7 explained below). According to one embodiment, the connector 45 is a doped semiconductor region of the same doping type as the third partial layer 230 and, therefore, complementary to the doping type of the first semiconductor layer 100. The doping concentration of the connector 45 is, for example, 10²⁰ cm⁻³ or more. The electrical connection between the second load terminal 13 and the connector 45 is only schematically illustrated in FIG. 5. This connection can be implemented in a conventional way using, for example, a metallization or the like.

The electrical connection between the first partial layer 210 and the first load terminal 12 is only schematically illustrated in FIG. 5. This electrical connection can be implemented in a conventional way using metallizations, bond wires or the like. According to one embodiment, the second surface 202 of the semiconductor body is mounted to an electrical conducting carrier (not shown), such as a lead frame, and the first load terminal 12 is electrically connected to the carrier using, for example, a bond wire.

In the embodiment illustrated in FIG. 5, the second semiconductor layer 200 adjoins the first semiconductor layer 100, so that a pn junction is formed between the first semiconductor layer 100 and the third partial layer 230 of the second semiconductor layer 200. The semiconductor body with the first semiconductor layer 100 and the second semiconductor layer 200 can be produced in many different ways.

According to one embodiment, a highly doped substrate forming the first partial layer 210 is provided. The second and third partial layer layers 220, 230 and the first semiconductor layer 100 are epitaxial layers formed on the substrate of this embodiment. According to a further embodiment, a substrate is provided having a basic doping corresponding to the doping concentration of the second partial layer 220. On this substrate the third partial layer 230 and the first semiconductor layer 100 are formed by an epitaxial growth process, while the first partial layer 210 is formed using an implantation and/or diffusion process. Instead of forming the third partial layer 230 as an epitaxial layer, the third partial layer could alternatively be produced by implanting and/or diffusing dopant atoms into the substrate before producing the first semiconductor layer 100. According to yet another embodiment, the first semiconductor layer 100 and the second semiconductor layer 200 with the three partial layers 210, 220, 230 are produced separately and are then joined using a wafer-bonding process.

FIG. 6 illustrates a vertical cross sectional view of a semiconductor body according to a further embodiment. The semiconductor body of FIG. 6 is different from the semiconductor body of FIG. 5 in that the second semiconductor layer 200 does not adjoin the first semiconductor layer 100, but is separated from the first semiconductor layer 100 by an insulation layer 300, such as an oxide layer. The conductor 45 extends through the insulation layer 300 to or into the third partial layer 230. The semiconductor body with the first semiconductor layer 100, the insulation layer 300, and the second semiconductor layer 200 can be produced using a wafer-boding process. In this process, the first semiconductor layer 100 and the second semiconductor layer 200 are produced separately, then one surface of the second semiconductor layer 200, namely the surface facing the first semiconductor layer 100, and one surface of the first semiconductor layer 100, namely the surface phasing the second semiconductor layer 200, are oxidized. Then the oxide layers on the surfaces of the first and second semiconductor layers 100, 200 are brought into contact and are joined in a thermal process, so that the two oxide layers form the insulation layer 300. Then, the switching device 1 and the connector 45 are produced. Of course, it is not one single semiconductor body (die) that is produced in the bonding process, but a wafer including a plurality of semiconductor bodies that are finally singularized.

Referring to the illustration in dashed lines in FIGS. 5 and 6, in the embodiments of FIGS. 5 and 6, as well as in the embodiments explained below, two symmetrical switching devices 1 can be formed in the first semiconductor layer 100, where each of these switching devices 1 has a first load terminal connected to the first load terminal 12, and a second load terminal connected to the load terminal 13.

The connector 45 connecting the second load terminal 13 with the third partial layer 230 is only schematically illustrated in FIGS. 5 and 6. Referring to the explanation before, the connector 45 may include a doped semiconductor material forming a pn-junction with the surrounding semiconductor material of the first semiconductor layer 100. According to a further embodiment, illustrated in FIG. 7, the connector may include an electrically conducting core that is electrically insulated form the surrounding semiconductor material.

FIG. 7 illustrates a cross sectional view of a section of the first semiconductor layer 100 in which the connector 45 is implemented. In this embodiment, the connector 45 includes an electrically conductive core 45₂ that is electrically insulated from the semiconductor layer 100 by an insulation layer 45₁ and that electrically connects the second load terminal with the third partial layer 230. The insulation layer is, for example, an oxide layer or a nitride layer. The electrical conducting core includes, for example, a highly doped monocrystalline or polycrystalline semiconductor material, or a metal. A connector as illustrated in FIG. 7 may be implemented in each of the embodiments explained before and explained below.

FIG. 8 illustrates an embodiment of an integrated circuit that is a modification of the integrated circuit illustrated in FIG. 5. In the embodiment of FIG. 8, a section of the semiconductor layer 100 is removed, so that a section of the third partial layer 230 is uncovered. In FIG. 8, reference character 231 denotes the surface of the third partial layer 230 in the uncovered region. The second load terminal 13 is electrically connected to the surface 231 of the third partial layer 230. The electrical connection can be obtained in a conventional manner using, for example, a metallization, or the like.

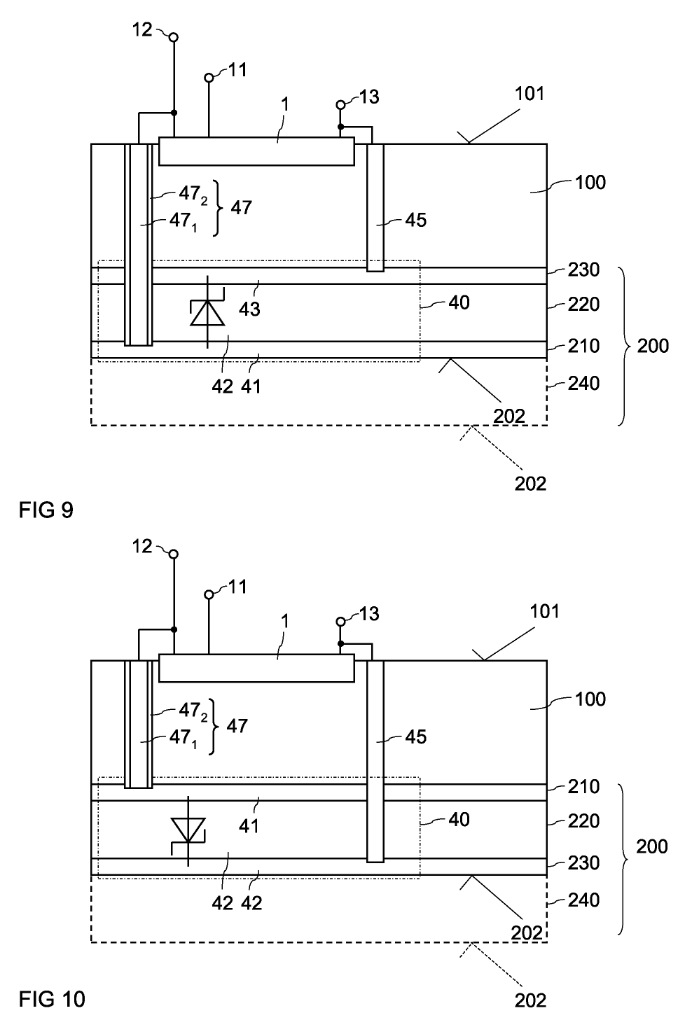

FIG. 9 illustrates a further embodiment of an integrated circuit. The embodiment of FIG. 9 is different from the embodiment of FIG. 5 in that the first partial layer 210, forming the first emitter 41 of the diode 40, is electrical connected to the first load terminal 12 through a second connector 47. The second connector 47 extends in a vertical direction of the semiconductor body through the first semiconductor layer 100, the third partial layer 230 and the second partial layer 220 to or into the first partial layer 210. In this embodiment, the second connector 47 includes an electrically conducting core 47₁, such as, for example, a highly doped polycrystalline or monocrystalline semiconductor material, or a metal, and an insulating layer 47₂ insulating the conducting core 47₁ from the surrounding semiconductor layers 100, 230, 220. In this embodiment, the first partial layer 210 has not to be accessible at the surface 202, so that in this embodiment the second semiconductor layer 200 may include a fourth partial layer 240 acting as a carrier or which the arrangement with the first partial layer 210, the second partial layer 220, the third partial layer 230 and the first semiconductor layer 100 are arranged. The doping type of the fourth partial layer 240 may correspond to the doping type of the first partial layer 210, may be complementary to the doping type of the first partial layer 210, or may be intrinsic.

FIG. 10 illustrates a modification of the integrated circuit of FIG. 9. In the integrated circuit of FIG. 10, the positions of the first and third partial layers 210, 230 are changed, so that the first partial layer 210 adjoins the first semiconductor layer 100. In this embodiment, the second conductor 47 only extends through the first semiconductor layer 100 to or into the first partial layer 210, while the first conductor 45 extends through the first semiconductor layer 100, the first partial layer 210 and the second partial layer 220 to or into the third partial layer 230. The first conductor 45 is, for example, implemented as illustrated in FIG. 7. The second conductor 47 can be implemented as illustrated in FIG. 9. In an alternative embodiment, the insulation layer 47₂ of the second conductor 47 is omitted. In this embodiment, the electrical conducting core 47₁ includes, for example, a highly doped monocrystalline semiconductor material.

In the embodiments of FIGS. 9 and 10 the second semiconductor layer 200 adjoins the first semiconductor layer 100. In accordance with the embodiment illustrated in FIG. 2, the embodiments of FIGS. 9 and 10 could be modified to include an insulation layer, such as an oxide layer, between the first and second semiconductor layers 100, 200. In the embodiment illustrated in FIG. 10, the connector 45 may be implemented as explained with reference to FIG. 7, namely with an electrically conductive core and with an electrically insulating material surrounding in a lateral direction of the semiconductor body.

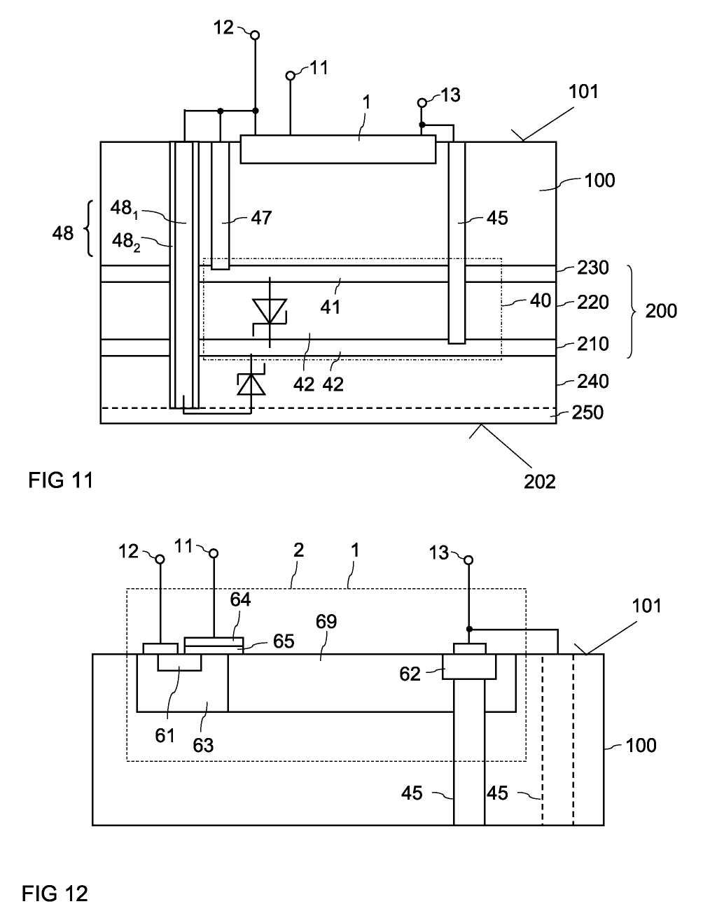

FIG. 11 illustrates a vertical cross sectional view of an integrated circuit according to a further embodiment. The embodiment of FIG. 11 is based on the embodiment of FIG. 10, specifically the alternative with the fourth partial layer 240 below the third partial layer 230, and additionally includes a third connector 48 electrically connected to the first load terminal 12 and extending through the first semiconductor layer 100, and the first, second and third partial layers 210, 220, 230 into the fourth partial layer 240 of the second semiconductor layer 200. The fourth partial layer 240 has a doping type that is complementary to the doping type of the first partial layer 210 so that a further pn junction is formed between the fourth partial layer 240 and the first partial layer 210. This pn junction forms a further diode or is part of a further diode between the third connector 48 and the first connector 45 and, therefore between the first and the second load terminal 12, 13. The circuit symbol of this further diode is also illustrated in FIG. 11. Optionally, the second semiconductor layer 200 includes a fifth partial layer of a doping type complementary to the doping type of the first partial layer 110 and more highly doped than the fourth partial layer 240. The third connector 48 extends to or into the fifth partial layer 250. In this embodiment, the fifth partial layer 250 and the first partial layers form emitter regions of the further diode and the fourth partial layer 240 forms the base region of the further diode, where in this embodiment, the fourth partial layer 240 either has a lower doping concentration than the fifth partial layer 250 or is intrinsic.

Optionally (and not illustrated in FIG. 11), the connection between the first load terminal 12 and the fourth partial layer 240 can be realized using an external wiring, e.g., from the first load terminal 12 to a lead frame, with the fourth partial layer 240 or the optional fifth partial layer 250 being mounted to the lead frame. A bond wire may be used to connect the first load terminal 12 to the lead frame like described before.

The third conductor 48 is implemented as the conductor 45 of FIG. 7 and includes an electrically conductive core 48, and an electrically insulating layer 48₂ insulating the core from the surrounding semiconductor material in a lateral direction of the semiconductor body.

The two diodes, namely the first diode formed by first, second and third partial layers 210, 220, 230 and the second diode formed by the first, fourth and the optional fifth partial layers 210, 240, 250 are connected in parallel between the first and the second load terminals 12, 13 and may have the same blocking capabilities or similar voltage blocking capabilities. The voltage blocking capabilities are similar, when a ratio between a first voltage blocking capability of the first diode and a second voltage blocking capability of the second diode is between 0.7 and 1.3, between 0.8 and 1.2, or between 0.9 and 1.1. The voltage blocking capability of the second diode can be adjusted through the doping concentration of the fourth partial layer 240 and the distance between the position where the conductive core 48₁ of the third conductor 48 is connected to the fourth partial layer 240 or the fifth partial layer 250 and the first partial layer 210. The fifth partial layer 250 may adjoin the second surface 202 and may be produced using an implantation and/or diffusion process.

In the integrated circuit of FIG. 11, the second load terminal 12 can be contacted via the second surface 202, which means by electrically contacting the second surface 202.

FIG. 12 illustrates a possible implementation of a switching device 1 including a first switching element 2. FIG. 12 shows a vertical cross sectional view of the first semiconductor layer 100 in the region of the first surface 101 where the first switching element 2 is implemented. The first switching element 2 is implemented as a lateral MOSFET and includes a source region 61 and a drain region 62 that are distant in a lateral direction of the semiconductor body 100. The MOSFET further includes a drift region 69 and a body region 63 forming a pn junction, where the body region 63 separates the source region 61 from the drift region 69 and the drift region 69 is located between the drain region 62 and the body region 63. A gate electrode 64 is adjacent the body region 63 and is dielectrically insulated from the body region 63 by a gate dielectric 65. The gate electrode 64 is electrically connected to the control terminal 11, the source region 61 and the body region 63 are electrically connected to the first load terminal (source terminal) 12, and the drain terminal 62 is electrically connected to the second load terminal (drain terminal) 13.

The gate electrode 64 is implemented as a planar gate electrode above the first surface 101. However, this is only an example. The gate electrode 64 could also be implemented as a trench electrode located in a trench extending in a vertical direction into the first semiconductor layer 100 from the first surface 101.

The connector 45 can be located below the drain region 62, so that it extends from the drain region 62 into the first semiconductor layer 100. According to a further embodiment (illustrated in dashed lines), the connector 45 is arranged distant to the drain region 62 in the lateral direction of the semiconductor layer 100 and is electrically connected to the second load terminal 13. The electrical connection between the second load terminal 13 and the connector 45 is only schematically illustrated.

Referring to FIG. 12, the body region 63 and the drift region 69 are embedded in the first semiconductor layer 100, so that the body region 63 and the drift region 69 are surrounded by a semiconductor region having the basic doping of the first doping type of the semiconductor layer 100. The body region 63 has the first doping type and, therefore, the same doping type as the basic doping of this first semiconductor layer 100, while the drift region 69 and the source region 61 have the second doping type complementary to the first doping type. The drain region 62 has the same doping type, when the second switching element 2 is implemented as a MOSFET, or has the first doping type, when the second switching element 2 is implemented as an IGBT.

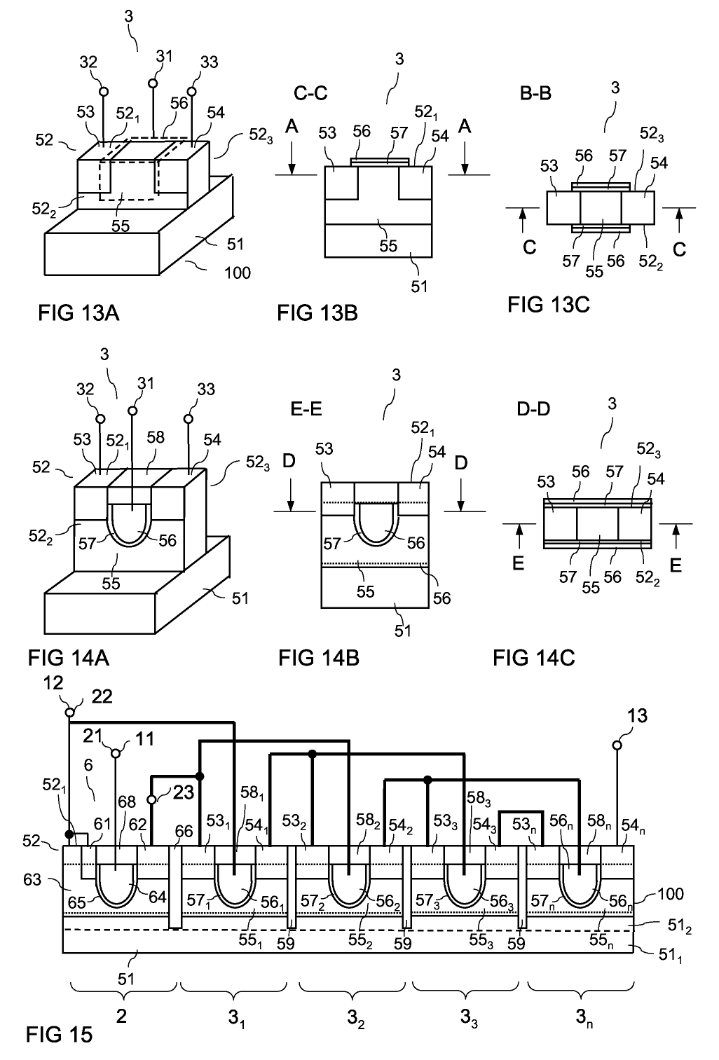

FIGS. 13 to 20 illustrate some illustrative embodiments for implementing the first switching element 2 and the second switching element 3 in integrated circuits as illustrated in FIGS. 3 and 4.

FIGS. 13A to 13B show a first embodiment of a second switching element 3 implemented in the first semiconductor layer 100. FIG. 13A shows a perspective view of the second switching element 3. FIG. 13B shows a vertical cross sectional view and FIG. 13C shows a horizontal cross sectional view of this second switching element 3. FIGS. 13A, 13B, 13C only show that section of the first semiconductor layer 100 in which the second switching element 3 is implemented. Active regions of the first switching element 2 and active regions of neighbouring second switching elements are not shown. Basically, the first switching element 2 can be implemented like the second switching elements. This is, for example, explained with reference to FIG. 15 below.

The second switching element 3 according to FIGS. 13A to 13C is implemented as a MOSFET, specifically as a FINFET, and includes a source region 53, a drain region 54 and a body region 55 that are each arranged in a fin-like semiconductor section 52, which will also be referred to as “semiconductor fin” in the following. The semiconductor fin 52 can be produced by forming two parallel trenches in the first surface 101 of the first semiconductor layer 100. The semiconductor region 51 below the semiconductor fin 53 will be referred to as substrate 51 in the following. The doping type and the concentration of the substrate may correspond to the doping type and the doping concentration of the basic doping of the first semiconductor layer 100 or can be different from the doping type and/or the doping concentration of the basic doping of the first semiconductor layer 100.

In a first horizontal direction, the source and drain regions 53, 54 extend from a first sidewall 52₂ to a second sidewall 52₃ of the semiconductor fin 52. In a second direction perpendicular to the first direction the source and drain regions 53, 54 are distant from one another and are separated by the body region 55. The gate electrode 56 (illustrated in dashed lines in FIG. 13A) is dielectrically insulated from the semiconductor fin 52 by a gate dielectric 57 and is adjacent to the body region 55 on the sidewalls 52₂, 52₃ and on a top surface 52₁ of semiconductor fin 52.

FIGS. 14A to 14C illustrate a further embodiment of one second switching element 3 implemented as a FINFET. FIG. 14A shows a perspective view, FIG. 14B shows a vertical cross sectional view in a vertical section plane E-E, and FIG. 14C shows a horizontal cross sectional view in horizontal section plane D-D. The vertical section plane E-E extends perpendicular to the top surface 52₁ of the semiconductor fin 52 and in a longitudinal direction of the semiconductor fin 52. The horizontal section plane D-D extends parallel to the top surface 52₁ of the semiconductor fin. The “longitudinal direction” of the semiconductor fin 52 corresponds to the second horizontal direction and is the direction in which the source and drain region 53, 54 are distant from one another.

The switching element 3 according to FIGS. 14A to 14C is implemented as a U-shape-surround-gate-FINFET. In this switching element, the source region 53 and the drain region 54 extend from the first sidewall 52₂ to the second sidewall 52₃ of the semiconductor fin 52 in the first horizontal direction, and are distant from one another in the second horizontal direction (the longitudinal direction of the semiconductor fin 52) that is perpendicular to the first horizontal direction. Referring to FIGS. 14A and 14B, the source region 53 and the drain region 54 are separated by a trench which extends into the body region 55 from the top surface 52₁ of the semiconductor fin and which extends from sidewall 52₂ to sidewall 52₃ in the first horizontal direction. The body region 55 is arranged below the source region 53, the drain region 54 and the trench in the semiconductor fin 52. The gate electrode 56 is adjacent to the body region 55 in the trench and along the sidewalls 52₂, 52₃ of the semiconductor fin 52 and is dielectrically insulated from the body region 55 and the source and drain regions 53, 54 by the gate dielectric 57. In an upper region of the trench, which is a region in which the gate electrode 56 is not arranged adjacent to the body region 55, the gate electrode 56 can be covered with an insulating or dielectric material 58.

The second switching elements of FIGS. 13A to 13C and of FIGS. 14A to 14C are, for example, implemented as depletion transistors, such as an n-type or a p-type depletion transistor. In this case, the source and drain regions 53, 54 and the body region 55 have the same doping type. The body region 55 usually has a lower doping concentration than the source and drain regions 53, 54. The doping concentration of the body region 55 is, e.g., about 2E18 cm⁻³. In order to be able to completely interrupt a conducting channel in the body region 55 between the source region 53 and the drain region 54, the gate electrode 56 along the sidewalls 52₂, 52₃ of the semiconductor fin 52 completely extends along the semiconductor fin 52 in the second horizontal direction (the longitudinal direction). In the vertical direction the gate electrode 56 along the sidewalls 52₂, 52₃ extends from the source and drain regions 53, 54 to at least below the trench.

Referring to FIGS. 13A and 14A, the source region 53 is connected to the first load terminal (source terminal) 32, the drain region 54 is connected to the second load terminal (drain terminal) 33, and the gate electrode 56 is connected to the control terminal (gate terminal) 31. These terminals are only schematically illustrated in FIGS. 13A and 14A.

A thickness of the semiconductor fin 52, which is the dimension of the semiconductor fin in the first horizontal direction, and the doping concentration of the body region 55 are adjusted such that a depletion region controlled by the gate electrode 56 can extend from sidewall 522 to sidewall 523 in order to completely interrupt a conducting channel between the source and the drain region 53, 54 and to switch the second switching element 3 off. In an n-type depletion MOSFET a depletion region expands in the body region 55 when a negative control (drive) voltage is applied between the gate electrode 56 and the source region 53 or between the gate terminal 31 and the source terminal 32, respectively. Referring to the explanation provided with reference to FIG. 3, this drive voltage is dependent on the load voltage of the first semiconductor device 2, or is dependent on the load voltage of another one of the second switching elements 3. How far the depletion region expands perpendicular to the sidewalls 522, 523 is also dependent on the magnitude of the control voltage applied between the gate terminal 31 and the source terminal 32. Thus, the thickness of the semiconductor fin 52 and the doping concentration of the body region 55 are also designed dependent on the magnitude of the control voltage that can occur during the operation of the semiconductor device arrangement.

Implementing the FINFETs illustrated in FIGS. 13A to 13C and 14A to 14C as U-shape-surround-gate-FINFET, in which the channel (body region) 55 has an U-shape and the gate electrode 56 is also arranged on sidewalls 522, 523 and on a top surface 521 of the semiconductor fin 52 is only an example. These FINFETs could also be modified (not illustrated) to have the gate electrode 56 implemented with two gate electrode sections arranged on the sidewalls 522, 523 but not on the top surface 521 of the semiconductor fin 52. A FINFET of this type can be referred to as double-gate FINFET. Each of the FINFETs explained above and below can be implemented as U-shape-surround-gate-FINFET or as double-gate FINFET. It is even possible to implement the individual second switching elements 3 as different types of MOSFETs or FINFETs in one integrated circuit.

Each of the second switching elements 3 and the first semiconductor device 2 can be implemented as FINFET. These individual FINFETs can be implemented in different ways to form the switching device 1.

FIG. 15 illustrates a vertical cross sectional view of a semiconductor fin 52 in which active regions (source, drain and body regions) of a first switching element 2 and of n second switching elements 3 are arranged. In this embodiment, the first switching element 2 and the second switching elements are implemented as U-shape-surround-gate FINFETs or as double-gate FINFETs. In FIG. 15, like reference numbers are used to denote like features as in FIGS. 13A to 13C and 14A to 14C. In FIG. 15 the reference numbers of like features of the different second switching elements 3₁-3ₙ have different indices (1, 2, 3, n).

Referring to FIG. 15, the active regions of neighboring second switching elements 3 are insulated from each other by dielectric layers 59 which extend in a vertical direction of the semiconductor fin 52. These dielectric layers 59 may extend down to or down into the substrate 51. Further, the dielectric layers 59 extend from sidewall to sidewall of the semiconductor fin 52. However, this is out of view in FIG. 15. The active regions of the first switching element 2 are dielectrically insulated from active regions of the 1st second switching element 3₁ by a further dielectric layer 66 that also extends in a vertical direction of the semiconductor fin 52. In the first switching element 2, a source region 61 and a drain region 62 are separated by a body region 63. The gate electrode 64 that is arranged in the trench (and the position of which at the sidewalls of the semiconductor fin is illustrated by dotted lines), extends from the source region 61 along the body region 63 to the drain region 62. The source region 61 is connected the first load terminal 22 that forms the first load terminal 12 of the semiconductor arrangement 1, the drain region 62 is connected to the second load terminal 23, and the gate electrode 64 is connected to the control terminal 21 that forms the control terminal 11 of the semiconductor arrangement 1. The body region 63 is also connected to the first load terminal 22.

The first switching element 2 is, for example, implemented as an enhancement MOSFET. In this case, the body region 63 is doped complementarily to the source and drain regions 61, 62. In an n-type MOSFET, the source and drain regions 61, 62 are n-doped while the body region 63 is p-doped, and in a p-type MOSFET, the source and drain regions 61, 62 are p-doped while the body region 63 is n-doped.

According to one embodiment, the substrate 51 is doped complementarily to the active regions of the second switching elements 3 and to the source and drain regions 61, 62 of the first switching element 2. In this case, there is a junction isolation between the individual second switching elements 3. When, for example, the first and second switching elements 2, 3 are n-type MOSFETs the substrate 51 can be p-doped. The substrate 51 may have a doping corresponding to the basic doping of the first semiconductor layer 100, in this embodiment.

According to a further embodiment (illustrated in dashed lines), the substrate 51 includes a semiconductor substrate 51₁ and an insulation layer 51₂ on the semiconductor substrate 51₁. The semiconductor fin 52 is arranged on the insulation layer 51₂. In this embodiment, there is a dielectric layer between the individual second switching elements 3 in the substrate 51. The doping of the semiconductor substrate 51₁ may correspond to the basic doping of the first semiconductor layer 100, in this embodiment.

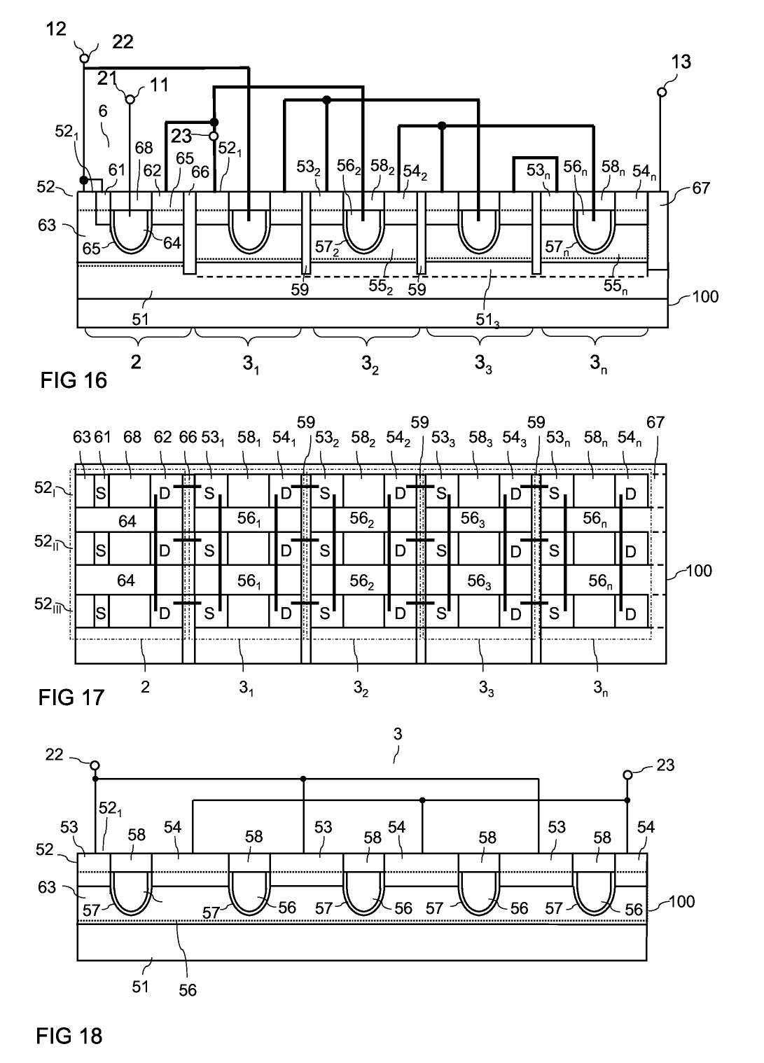

According to yet another embodiment, illustrated in FIG. 16, the substrate 51 has the same doping type as the active regions of the second switching elements 3 and as the source and drain regions 61, 62 of the first switching element 2. In this embodiment, the gate electrode 56 of the first switching element 2 extends to the substrate, so that there is a conducting path in the body region between the source region 61 and the substrate 51 when the first switching element 2 is in the on-state. In this embodiment, the substrate 51 has a doping type that is complementary to the doping type of the basic doping of the first semiconductor layer 100. The substrate 51 adjoins the region of the first semiconductor layer 100 having the basic doping of the first doping type.

Furthermore, the substrate 51 is connected to the second load terminal 13 of the semiconductor arrangement through a contact region 67 of the same doping type as the substrate 51. The contact region 67 is more highly doped than the substrate 51 and extends from the first surface 52₁ of the semiconductor fin 52 to the substrate. The contact region 67 may adjoin the drain region 54ₙ of the n-th second switching element 3. The contact region 67 is optional. A connection between the second load terminal 13 and the substrate 51 could also be provided through the drain and body regions 54ₙ, 55ₙ of the second switching element 3ₙ.

In the semiconductor arrangement of FIG. 16, the substrate 51 forms a current path that is parallel to the current path through the second switching elements 3 or that is parallel to the ADZ. The substrate 51 is similar to the drift region in a conventional power switching element. In this embodiment, the body regions 55 of the individual second switching elements 3 are coupled to the drift region 51.

According to further embodiment (illustrated in dashed lines in FIG. 16) the substrate 51 includes a semiconductor layer 51₃ doped complementary to remaining sections of the substrate 51 and to the body regions 55 of the second switching elements 3. This layer 51₃ is arranged between the body regions 55 of the second switching elements 3 and those sections of the substrate acting as a drift region and provides a junction insulation between the individual second switching elements 3 in the substrate 51.

Each of the first switching element 2 and the second switching elements 3 (referred to as devices in the following) may include a plurality of identical cells (transistor cells) that are connected in parallel. Each of these cells can be implemented like the first switching element 2 or like the second switching elements 3, respectively, illustrated in FIGS. 13 and 14. Providing a plurality of cells connected in parallel in one device can help to increase the current bearing capability and to reduce the on-resistance of the individual device.

FIG. 17 illustrates a top view on a semiconductor arrangement according to a first embodiment which includes a first switching element 2 and a plurality of second switching elements 3, with each of these devices having a plurality (from which three are illustrated) cells connected in parallel. The individual cells of one device are implemented in different semiconductor fins 52_{I}, 52_{II}, 52_{III}. Each of these cells has a source region 61, 53 that is additionally labeled with “S” in FIG. 17, and a drain region 62, 54 that is additionally labeled with “D” in FIG. 17. The cells of one device are connected in parallel by having the source regions of the one device connected together and by having the drain regions of the one device connected together. These connections as well as connections between the load terminals of the different devices are schematically illustrated in bold lines in FIG. 17. Connections between the control terminals (gate terminals) and the load terminals of the different devices are not illustrated in FIG. 17. The connections between the cells and the different devices can be implemented using conventional wiring arrangements arranged above the semiconductor body and contacting the individual active regions (source and drain regions) through vias. Those wiring arrangements are commonly known so that no further explanations are required in this regard. The individual cells of one device 2, 3₁, 3₂, 3₃, 3ₙ have a common gate electrode 64, 56₁, 56₂, 56₃, 56ₙ arranged in the U-shaped trenches of the individual semiconductor fins and in trenches between the individual fins. These “trenches between the fins” are longitudinal trenches along the fins. All gates 64, 56₁, 56₂, 56₃, 56ₙ are electrically isolated from each other by a dielectric 66 and 59.

FIG. 18 illustrates a further embodiment for implementing one second switching element 3 with a plurality of transistor cells. In this embodiment, a plurality of transistor cells of the second switching element 3 are implemented in one semiconductor fin. In the longitudinal direction of the semiconductor fin 52, source and drain regions 53, 54 are arranged alternatingly with a source region 53 and a neighboring drain region 54 being separated by one (U-shaped) trench that accommodates the gate electrode 56. The source regions 53 are connected to the first load terminal 22, and the drain regions 54 are connected to the second load terminal 23, so that the individual transistor cells are connected in parallel. The gate electrode 56 is common to the individual transistor cells and extends along the sidewalls of the semiconductor fin 52 in the longitudinal direction. Each source region 53 and each drain region 54 (except for the source and drain regions arranged at the longitudinal ends of the semiconductor fin 52) is common to two neighboring transistor cells.

The concept of providing several transistor cells in one semiconductor fin explained with reference to FIG. 18 is, of course, also applicable to the implementation of the first switching element 2.

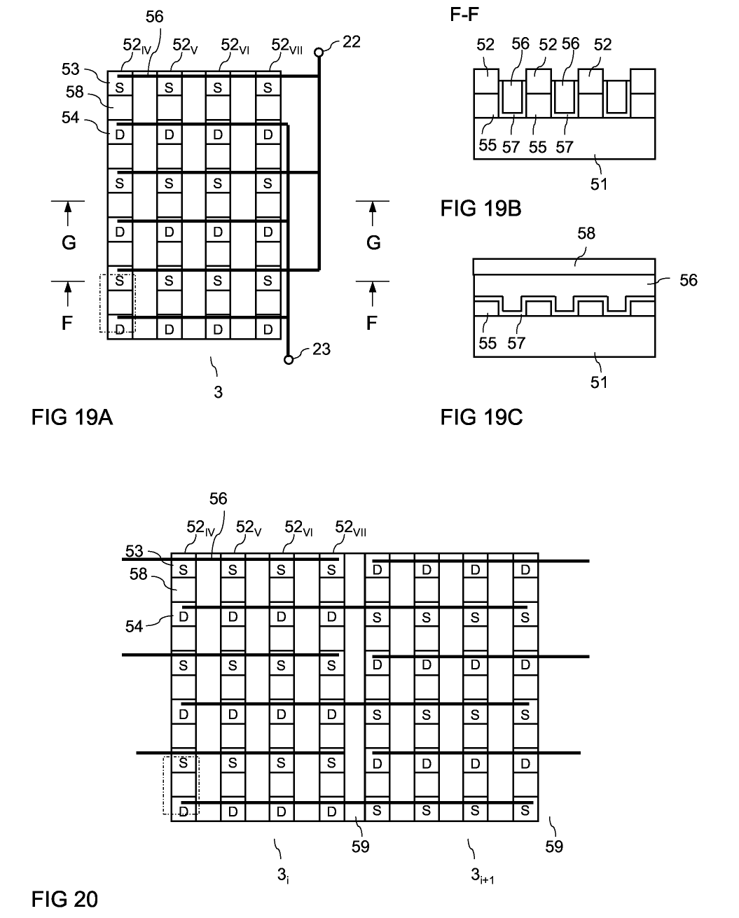

Referring to FIGS. 19A to 19C, one second switching element 3 may include a plurality of semiconductor fins 52_{IV}, 52_{V}, 52_{VI}, 52_{VII}, with each semiconductor fin 52_{IV}-52_{VII} including a plurality of transistor cells (one of these cells is highlighted by a dashed and dotted frame in FIG. 19A). FIG. 19A shows a top view of one second switching element 3, FIG. 19B shows a vertical cross sectional view in a section plane F-F cutting through source regions in different fins, and FIG. 19C shows a vertical cross sectional view in a section plane G-G cutting through the trenches with the gate electrode 56 in different fins. Referring to FIG. 19A, the source regions of the individual transistor cells are connected to the first load terminal 22 and the drain regions of the individual transistor cells are connected to the second load terminal 23 so that the individual transistor cells are connected in parallel. These connections are only schematically illustrated in FIG. 19A.

The concept of providing a plurality of semiconductor fins with each semiconductor fin including a plurality of transistor cells explained with reference to FIGS. 19A to 19C is, of course, also applicable to the implementation of the first switching element 2.

Although only 20 transistor cells are illustrated in FIG. 19A, namely five cells in each of the four semiconductor fins 52_{IV}-52_{VII}, one second switching element 3 or the first switching element 2 may include up to several thousand or even up to several ten or several hundred million transistor cells connected in parallel. The individual transistor cells form a matrix of transistor cells that are connected in parallel. A device (first switching element 2 or second switching element 3) having a plurality of transistor cells arranged in a matrix will be referred to as matrix device in the following.

FIG. 20 illustrates how second switching elements implemented as matrix devices can be connected in series. For illustration purposes, only two second switching elements 3ᵢ, 3ᵢ₊₁ are shown in FIG. 20. For connecting these two switching elements in series, the source regions of the second switching element 3ᵢ₊₁ are connected to the drain regions of the switching element 3ᵢ. The source regions of the second switching element 3ᵢ are connected to the drain regions of second switching elements 3ᵢ₋₁ (not illustrated), and the drain regions of the second switching element 3ᵢ₊₁ are connected to the source regions of second switching elements 3ᵢ₊₂ (not illustrated).

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

1. An integrated circuit comprising:
a semiconductor body with a first semiconductor layer and a second semiconductor layer arranged adjacent the first semiconductor layer in a vertical direction of the semiconductor body;
a switching device with a control terminal and a load path between a first load terminal and a second load terminal;
a rectifier element connected in parallel with at least one section of the load path; and
wherein the switching device is integrated in the first semiconductor layer and the rectifier element is integrated in the second semiconductor layer.

2. The integrated circuit of claim 1, wherein the second semiconductor layer comprises:
a first partial layer of a first doping type;
a second partial layer of a second doping type complementary to the first doping type; and
wherein the first partial layer is electrically coupled to the first load terminal and the second partial layer is electrically coupled to the second load terminal.

3. The integrated circuit of claim 2, wherein the second semiconductor layer further comprises:
a third partial layer arranged between the first partial layer and the second partial layer and having a lower doping concentration than the first partial layer and the second partial layer or being intrinsic.

4. The integrated circuit of claim 2, wherein the first semiconductor layer is of the first doping type.

5. The integrated circuit of claim 1, wherein the second semiconductor layer adjoins the first semiconductor layer.

6. The integrated circuit of claim 2, wherein the second partial layer adjoins the first semiconductor layer.

7. The integrated circuit of claim 2, wherein the first partial layer adjoins the first semiconductor layer.

8. The integrated circuit of claim 1, further comprising an insulation layer arranged between the first semiconductor layer and the second semiconductor layer.

9. The integrated circuit of claim 2, further comprising:
a first connector vertically extending through the first semiconductor layer to the second partial layer in the second semiconductor layer and connected to the second load terminal.

10. The integrated circuit of claim 9, wherein the first connector comprises:
a doped semiconductor region of a doping type complementary to a doping type of the first semiconductor layer.

11. The integrated circuit of claim 9, wherein the first connector comprises:
an electrically conducting region; and
an insulation region insulating the electrically conducting region from the first semiconductor layer.

12. The integrated circuit of claim 2, further comprising:
a trench extending through the first semiconductor layer to the second partial layer in the second semiconductor layer; and
a connector connected to the second partial layer in the trench and connected to the second load terminal.

13. The integrated circuit of claim 2, further comprising:
a second connector vertically extending through the first semiconductor layer to the first partial layer in the second semiconductor layer and connected to the first load terminal.

14. The integrated circuit of claim 13, wherein the second connector comprises:
a doped semiconductor region of the doping type of the first semiconductor layer.

15. The integrated circuit of claim 13, wherein the second connector comprises:
an electrically conducting region;
an insulation region insulating the electrically conducting region from the first semiconductor layer.

16. The integrated circuit of claim 1, wherein the switching device further comprises:
a first switching element with a load path coupled between the first load terminal and the second load terminal of the switching device, and with a control terminal coupled to the control terminal of the switching device.

17. The integrated circuit of claim 16, wherein the switching device further comprises:
a plurality of second switching elements, each having a load path between a first and a second load terminal and a control terminal; and
wherein the plurality of second switching elements have their load paths connected in series and connected in series to the load path of the first switching element; wherein each of the second switching elements has its control terminal connected to the load terminal of one of the other second switching elements; and
wherein one of the second switching elements has its control terminal connected to one of the load terminals of the first switching element.

18. The integrated circuit of claim 16, wherein the first switching element is an enhancement MOSFET.

19. The integrated circuit of claim 17,
wherein the first switching element is an enhancement MOSFET; and
wherein the second switching elements are depletion MOSFETs.

20. The integrated circuit of claim 19, wherein the enhancement MOSFET is a FINFET.

21. The integrated circuit of claim 19, wherein the enhancement MOSFET includes a plurality of transistor cells connected in parallel.

22. The integrated circuit of claim 19, wherein each depletion MOSFET is a FINFET.

23. The integrated circuit of claim 22, wherein each depletion MOSFET includes a plurality of transistor cells connected in parallel.

24. An integrated circuit comprising:
a semiconductor body with a first semiconductor layer and a second semiconductor layer arranged adjacent the first semiconductor layer in a vertical direction of the semiconductor body;
a switching device with a control terminal and a load path between a first load terminal and a second load terminal;
a rectifier element connected in parallel with at least one section of the load path; and
wherein the switching device is integrated in the first semiconductor layer and the rectifier element is integrated in the second semiconductor layer; and
wherein the connection between the rectifier element and the switching device comprises a first connector that is internal to the semiconductor body.
